(19) United States
(12) Patent Application Publication
(10) Pub. No.: US 2025/0031521 A1
(43) Pub. Date: Jan. 23, 2025

(54) DISPLAY DEVICE, MOBILE ELECTRONIC DEVICE INCLUDING THE SAME, AND MANUFACTURING METHOD THEREOF

(71) Applicant: SAMSUNG DISPLAY CO., LTD., YONGIN-SI, GYEONGGI-DO (KR)

(72) Inventor: CHUN GI YOU, Yongin-si (KR)

(21) Appl. No.: 18/734,185

(22) Filed: Jun. 5, 2024

(30) Foreign Application Priority Data
Jul. 18, 2023 (KR) 10-2023-0093195

(51) Int. Cl. H10K 59/121; G02B 27/01; H10K 59/12; H10K 59/131; H10K 59/38; H10K 59/80

(52) U.S. Cl. CPC H10K 59/1213; G02B 27/0172; H10K 59/1201; H10K 59/131; H10K 59/38; H10K 59/873; G02B 2027/0178

(57) ABSTRACT

A display device includes a substrate having a first surface and a second surface opposite to each other, a first driving element layer disposed on the first surface of the substrate and including a display driving circuit, at least one insulating layer disposed on the first driving element layer, a light emitting element layer including a light emitting element and disposed on the at least one insulating layer, an encapsulation layer disposed on the light emitting element layer, a second driving element layer disposed on the second surface of the substrate and including a plurality of pixel driving circuits electrically connected to the light emitting element through a first through-substrate via penetrating the substrate, the first driving element layer, and the at least one insulating layer, and a protective layer disposed on the second driving element layer.

### CROSS-REFERENCE TO RELATED APPLICATION

This application claims priority from Korean Patent Application No. 10-2023-0093195 filed on Jul. 18, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device, a mobile electronic device including the same, and a manufacturing method thereof.

### 2. Description of the Related Art

A wearable device designed in the form of glasses or a helmet and focused at a distance close to the user's eyes is being developed. For example, the wearable device may be a head mounted display (HMD) device or an augmented reality (AR) glass. Such a wearable device provides a user with an AR screen or a virtual reality (hereinafter, referred to as “VR”) screen.

The wearable device such as the HMD device or the AR glass is desirable with a display specification of at least 2,000 pixels per inch (PPI) to allow the user to use the device for a long time without feeling dizzy. To this end, organic light emitting diode on silicon (OLEDoS) technology, which is a small organic light emitting display device with high resolution, is emerging. In the OLEDoS, organic light emitting diodes (OLEDs) are disposed on a semiconductor wafer substrate at which a complementary metal oxide semiconductor (CMOS) is disposed.

### SUMMARY

Aspects of the present disclosure provide a display device capable of reducing power consumption by including a display panel capable of low-frequency driving, a mobile electronic device including the same, and a manufacturing method thereof.

According to an aspect of the present disclosure, a display device includes a substrate having a first surface and a second surface opposite to each other, a first driving element layer disposed on the first surface of the substrate and including a display driving circuit, at least one insulating layer disposed on the first driving element layer, a light emitting element layer including a light emitting element and disposed on the at least one insulating layer, an encapsulation layer disposed on the light emitting element layer, a second driving element layer disposed on the second surface of the substrate and including a plurality of pixel driving circuits electrically connected to the light emitting element through a first through-substrate via penetrating the substrate, the first driving element layer, and the at least one insulating layer, and a protective layer disposed on the second driving element layer, wherein the second driving element layer is disposed between the second surface of the substrate and the protective layer.

The plurality of pixel driving circuits of the second driving element layer may be electrically connected to the display driving circuit through a second through-substrate via penetrating the substrate.

The substrate includes a display area at which a plurality of pixels including the light emitting element are disposed, and a non-display area outside the display area, the display driving circuit is disposed at the non-display area, and the plurality of pixel driving circuits overlap the display area at which the plurality of pixels are disposed.

The plurality of pixel driving circuits are connected to a fan-out line extending from the display area to the non-display area, and one end of the fan-out line is electrically connected to the display driving circuit through the second through-substrate via penetrating the non-display area of the substrate.

The first through-substrate via penetrates the display area of the substrate.

Each of the plurality of pixel driving circuits may include an oxide semiconductor thin film transistor.

The display device may further include a color filter layer disposed on the encapsulation layer and including a color filter, a light control layer disposed on the color filter layer and including a refractive film, and a cover window disposed on the light control layer.

According to an aspect of the present disclosure, a manufacturing method of a display device includes preparing a substrate, forming a first driving element layer including a display driving circuit on a first surface of the substrate, forming at least one insulating layer on the first driving element layer, forming a light emitting element layer including a light emitting element on the at least one insulating layer, forming an encapsulation layer on the light emitting element layer, performing a chemical mechanical polishing (CMP) process on a second surface, opposite to the first surface, of the substrate to expose a first through-substrate via electrically connected to the light emitting element and extending from the first surface toward the second surface, forming a second driving element layer including a plurality of pixel driving circuits on the second surface of the substrate, wherein the plurality of pixel driving circuits are connected to the light emitting element through the first through-substrate via, and forming a protective layer on the second driving element layer, wherein the second driving element layer is disposed between the protective layer and the second surface of the substrate.

The first through-substrate via may penetrate the substrate, the first driving element layer, and the at least one insulating layer.

The plurality of pixel driving circuits of the second driving element layer may be electrically connected to the display driving circuit through a second through-substrate via penetrating the substrate.

The substrate includes a display area at which a plurality of pixels including the light emitting element are disposed, and a non-display area outside the display area, the display driving circuit is disposed at the non-display area, and the plurality of pixel driving circuits overlap the display area at which the plurality of pixels are disposed.

The plurality of pixel driving circuits are connected to a fan-out line extending from the display area to the non-display area, and one end of the fan-out line is electrically connected to the display driving circuit through the second through-substrate via penetrating the non-display area of the substrate.

The plurality of pixel driving circuits may be electrically connected to the light emitting element through the first through-substrate via penetrating the display area.

Each of the plurality of pixel driving circuits may include an oxide semiconductor thin film transistor.

The manufacturing method may include forming a color filter layer including a color filter on the encapsulation layer, forming a light control layer on the color filter layer, and attaching a cover window to the light control layer.

According to an aspect of the present disclosure, a mobile electronic device includes a display device including a substrate having a first surface and a second surface opposite to each other, a first driving element layer disposed on the first surface of the substrate and including a display driving circuit, at least one insulating layer disposed on the first driving element layer, a light emitting element layer including a light emitting element and disposed on the at least one insulating layer, an encapsulation layer disposed on the light emitting element layer, a second driving element layer disposed on the second surface of the substrate and including a plurality of pixel driving circuits electrically connected to the light emitting element through a first through-substrate via penetrating the substrate, the first driving element layer, and the at least one insulating layer, and a protective layer disposed on the second driving element layer, wherein the second driving element layer is disposed between the second surface of the substrate and the protective layer.

The plurality of pixel driving circuits of the second driving element layer may be electrically connected to the display driving circuit through a second through-substrate via penetrating the substrate.

The substrate includes a display area at which a plurality of pixels including the light emitting element are disposed, and a non-display area outside the display area, the display driving circuit is disposed at the non-display area, and the plurality of pixel driving circuits overlap the display area at which the plurality of pixels are disposed.

The plurality of pixel driving circuits are connected to a fan-out line extending from the display area to the non-display area, and one end of the fan-out line is electrically connected to the display driving circuit through the second through-substrate via penetrating the non-display area of the substrate.

Each of the plurality of pixel driving circuits includes an oxide semiconductor thin film transistor.

According to the display device, the mobile electronic device including the same, and the manufacturing method thereof according to the embodiments, power consumption may be reduced by including the display panel capable of low-frequency driving.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment of the present disclosure;

FIG. 2 is a plan view illustrating a front surface of a display panel according to an embodiment of the present disclosure;

FIG. 3 is a plan view illustrating a rear surface of the display panel according to an embodiment of the present disclosure;

FIG. 4 is a configuration block diagram of the display device according to an embodiment of the present disclosure;

FIG. 5 is a circuit diagram of one pixel of the display device according to an embodiment of the present disclosure.

FIG. 6 is a view illustrating a driving timing of a pixel driving circuit illustrated in FIG. 5 of the present disclosure;

FIG. 7 is a view schematically illustrating a stacked structure of each of a non-display area and a display area of the display panel according to an embodiment of the present disclosure;

FIG. 8 is a cross-sectional view of each of the non-display area and the display area of the display panel according to an embodiment of the present disclosure;

FIG. 9 is a flowchart illustrating at least a portion of a process of manufacturing a display device according to an embodiment of the present disclosure;

FIG. 10 is a view illustrating a step of preparing a semiconductor wafer substrate according to an embodiment of the present disclosure;

FIG. 11 is a view illustrating a step of forming a CMOS layer on a front surface of the semiconductor wafer substrate according to an embodiment of the present disclosure;

FIG. 12 is a view illustrating a step of forming a wiring layer, a light emitting element layer, an encapsulation layer, a color filter layer, a light control layer and a cover window on the CMOS layer according to an embodiment of the present disclosure;

FIG. 13 is a view illustrating a step of a chemical mechanical polishing (CMP) process according to an embodiment of the present disclosure;

FIG. 14 is a view illustrating a step of forming a transistor layer and a protective layer on a rear surface of the semiconductor wafer substrate according to an embodiment of the present disclosure;

FIG. 15 illustrates a virtual reality device including the display device according to an embodiment of the present disclosure; and

FIGS. 16 and 17 illustrate a head mounted display device to which the display device according to an embodiment is applied according to an embodiment of the present disclosure.

### DETAILED DESCRIPTION OF THE EMBODIMENTS

The present invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Hereinafter, specific embodiments will be described with reference to the accompanying drawings.

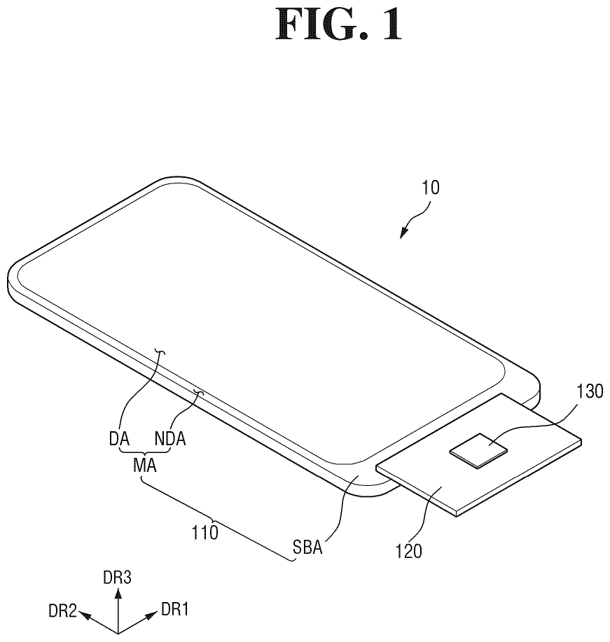

FIG. 1 is a perspective view illustrating a display device according to an embodiment.

Referring to FIG. 1, a display device 10 may be applied to portable electronic devices such as a mobile phone, a smartphone, a tablet personal computer (PC), a mobile communication terminal, an electronic notebook, an electronic book, a portable multimedia player (PMP), navigation device, and an ultra mobile PC (UMPC). For example, the display device 10 may be applied to a display unit of a television, a laptop computer, a monitor, a billboard, or the Internet of Things (IoT) device. In an embodiment, the display device 10 may be applied to a wearable device such as a smart watch, a watch phone, a glasses-type display, and a head mounted display (HMD) device.

The display device 10 may be formed in a planar shape similar to a quadrangle. For example, the display device 10 may have a planar shape similar to a quadrangle having a short side in a horizontal direction DR1 and a long side in a vertical direction DR2. In FIG. 1, DR3 indicates a normal direction perpendicular to a plane defined by the horizontal direction DR1 and the vertical direction DR2. A corner where the short side and the long side meet may be formed to be rounded to have a predetermined curvature or formed at a right angle. The planar shape of the display device 10 is not limited to the quadrangle, and may be formed similarly to other polygons, circles, or ovals.

The display device 10 includes a display panel 110, a circuit board 120, and a power supply unit 130.

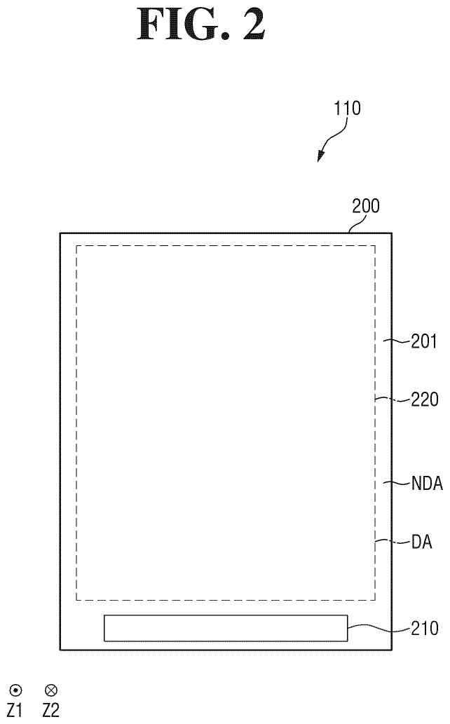

The display panel 110 is a display panel 110 using a semiconductor wafer substrate 200 (see FIG. 2) as a base substrate. The display panel 110 may include a main area MA and a sub-area SBA.

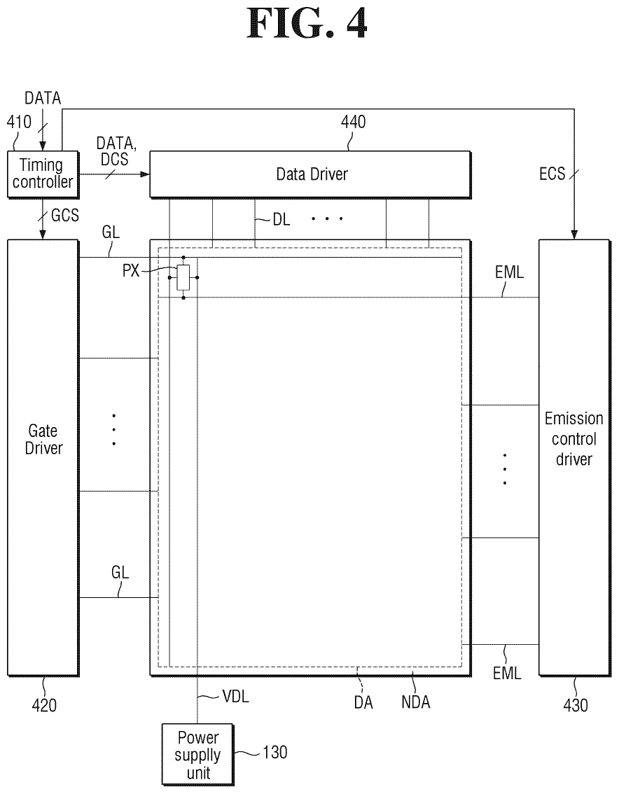

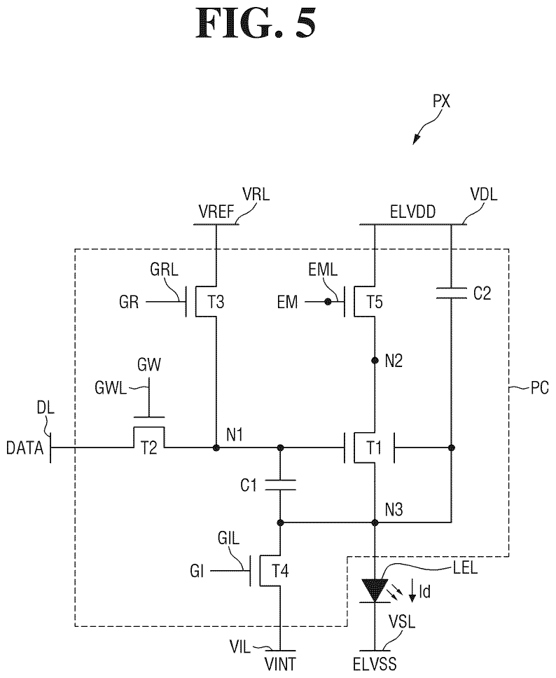

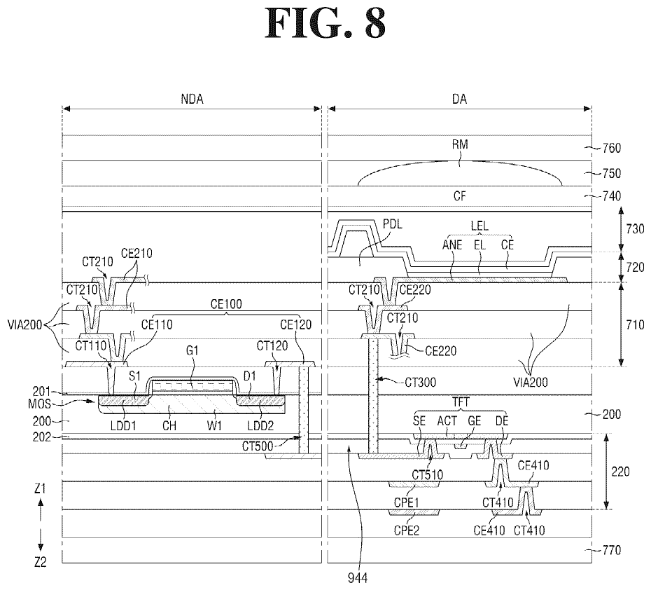

The main area MA may include a display area DA including pixels (PX in FIG. 4) displaying an image, and a non-display area NDA disposed around the display area DA. In an embodiment, the non-display area NDA may surround the display area DA. In an embodiment, the non-display area NDA may be adjacent to the display area DA. The non-display area NDA may refer to an area other than the display area DA. The display area DA may emit light from a plurality of light emitting areas or a plurality of opening areas. For example, the display panel 110 may include a pixel driving circuit (PC in FIG. 5) including switching elements, a pixel defining film defining a light emitting area or an opening area, and a light emitting element (LEL in FIG. 8) that is a self-light emitting element.

The light emitting element LEL may include at least one of an organic light emitting diode (LED) including an organic light emitting layer, a quantum dot LED including a quantum dot light emitting layer, an inorganic LED including an inorganic semiconductor, and a micro LED. However, the present disclosure is not limited thereto.

The non-display area NDA may be an area outside the display area DA. The non-display area NDA may be defined as an edge area of the main area MA of the display panel 110. The non-display area NDA may include fan-out lines (not illustrated) extending from lines (e.g., a gate line, a data line, and an emission control line) of the display area DA (that is, fan-out lines may extend from the display area DA to the non-display area NDA) and a display pad portion (not illustrated) connecting the fan-out lines and a display driving circuit 210 (see FIG. 2) disposed on a front surface of the semiconductor wafer substrate 200 (see FIG. 2).

The sub-area SBA may extend from one side of the main area MA. The sub-area SBA may include a main pad portion connected to the circuit board 120. The sub-area SBA may be omitted, and the main pad portion may be disposed in the non-display area NDA.

The circuit board 120 may be attached onto the main pad portion of the display panel 110 using an anisotropic conductive film (ACF). Lead lines of the circuit board 120 may be electrically connected to the main pad portion of the display panel 110. The circuit board 120 may be a flexible printed circuit board, a printed circuit board, and a flexible film such as a chip on film.

The power supply unit 130 may be disposed on the circuit board 120, and may supply a power voltage to the display driving circuit 210 and the display panel 110. The power supply unit 130 may generate a driving voltage and supply the driving voltage to a first driving voltage line VDL (see FIG. 4), and may generate a common voltage and supply the common voltage to a common electrode (e.g., a cathode electrode CE in FIG. 8) common to the light emitting elements LEL of the plurality of pixels PX. For example, the driving voltage may be a high potential voltage for driving the light emitting element LEL, and the common voltage may be a low potential voltage for driving the light emitting element LEL.

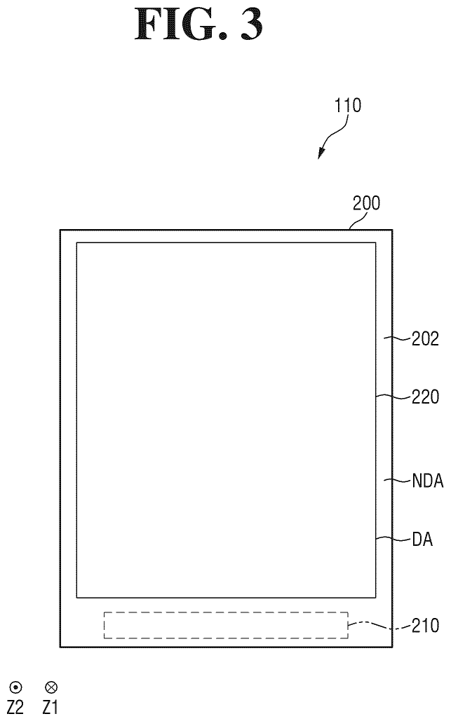

FIG. 2 is a plan view illustrating a front surface (i.e., a first surface) of a display panel according to an embodiment. FIG. 3 is a plan view illustrating a rear surface (i.e., a second surface) of the display panel according to an embodiment. In FIG. 2, components disposed on the front surface 201 of the display panel 110 are illustrated as solid lines, and components disposed on the rear surface 202 of the display panel 110 are illustrated as dotted lines. In FIG. 3, components disposed on the rear surface 202 of the display panel 110 are illustrated as solid lines, and components disposed on the front surface 201 of the display panel 110 are illustrated as dotted lines.

Referring to FIG. 2, the display panel 110 may be an organic light emitting diode on silicon (OLEDoS) panel using the semiconductor wafer substrate 200 as a base substrate. For example, the display panel 110 may include the semiconductor wafer substrate 200, and a complementary metal oxide semiconductor (CMOS) layer at which the display driving circuits 210 may be disposed on the front surface 201 of the display panel 110, which corresponds to a front surface of the semiconductor wafer substrate 200. The CMOS forming the display driving circuit 210 may include a field effect transistor, for example, an n-type metal oxide semiconductor field effect transistor (MOSFET) and/or a p-type MOSFET. Herein, the CMOS layer may be referred to as a “first driving element layer”. Herein, the semiconductor wafer substrate 200 may be referred to as a “substrate” or a “circuit board”.

Referring to FIG. 3, a transistor layer 220 including pixel driving circuits (PC in FIG. 5) is disposed on the rear surface 202 of the display panel 110, which corresponds to a rear surface of the semiconductor wafer substrate 200. The transistor layer 220 may include pixel driving circuits PC for driving light emitting elements (LEL in FIG. 8), lines (e.g., gate lines, data lines, and emission control lines) connected to the pixel driving circuits PC, and fan-out lines extending from the lines to the non-display area NDA. The fan-out lines may be electrically connected to the display driving circuit 210 (i.e., the CMOS layer) disposed on the front surface 201 of the semiconductor wafer substrate 200 through a contact hole (a second contact hole CT500 in FIG. 8) penetrating through the semiconductor wafer substrate 200. Herein, the transistor layer 220 may be referred to as a “second driving element layer”.

Each of the pixel driving circuits PC may be a circuit that drives a corresponding one of the plurality of pixels PX disposed in the display area DA, and may include a plurality of thin film transistors (T1, T2, T3, T4, and T5 in FIG. 5) and one or more capacitors (C1 and C2 in FIG. 5). The plurality of thin film transistors T1, T2, T3, T4, and T5 included in the pixel driving circuits PC may include oxide-based thin film transistors (i.e., a metal oxide semiconductor thin film transistor of which a channel layer includes an oxide semiconductor material such as indium oxide (In₂O₃), zinc oxide (ZnO), tin oxide (SnO₂), and a combination thereof).

Herein, the front surface 201 of the semiconductor wafer substrate 200 indicates a surface facing a first direction Z1 (e.g., a first normal direction) from the semiconductor wafer substrate 200. The rear surface 202 of the semiconductor wafer substrate 200 indicates a surface facing a second direction Z2 (e.g., a second normal direction) opposite to the first direction Z1 from the semiconductor wafer substrate 200. Herein, the first direction Z1 indicates a normal direction of the front surface 201, and is directed away from the front surface 201. A field effect transistor (e.g., MOSFET) of the CMOS layer to constitute the display driving circuit 210 is formed from the semiconductor wafer substrate 200 in the first direction Z1. In an embodiment, a channel layer of the field effect transistor may be formed at an upper portion of the semiconductor wafer substrate 200 which is adjacent to the front surface 201 of the semiconductor wafer substrate 200, and source/drain electrodes and a gate electrode may be disposed on the front surface 201. For example, the channel layer, and the gate electrode are stacked in the first direction Z1, and the gate electrode is higher than the channel layer in the first direction Z1, and the channel layer and the source/drain electrodes are stacked in the first direction Z1, and the source/drain electrodes are higher than the channel layer in the first direction Z1. Herein, the second direction Z2 indicates a normal direction of the rear surface 202, and is directed away from the rear surface 202. The second direction Z2 is opposite to the first direction Z1.

FIG. 4 is a configuration block diagram of the display device according to an embodiment.

Referring to FIG. 4, the display device 10 includes a display panel 110 employing the semiconductor wafer substrate 200. The display driving circuit 210 is embedded in the display panel 110. The display driving circuit 210 is formed at the CMOS layer disposed at the front surface 201 of the semiconductor wafer substrate 200. The display driving circuit 210 may include a timing controller 410, a gate driver 420, an emission control driver 430, and a data driver 440 as illustrated in FIG. 4, but the present disclosure is not limited thereto. In an embodiment, although not illustrated, the display driving circuit 210 may further include a memory, an interface circuit, an image processing circuit, and/or a gamma circuit.

The display panel 110 may include a display area DA and a non-display area NDA. For example, the front surface 201 of the semiconductor wafer substrate 200 may be divided into the display area DA and the non-display area NDA.

The display area DA may include a plurality of pixels PX, and a plurality of lines (e.g., a plurality of first driving voltage lines VDL, a plurality of gate lines GL, a plurality of emission control line EML, and a plurality of data lines DL) connected to the pixels PX. In the display area DA, a plurality of pixels PX may be formed at the front surface 201. The plurality of first driving voltage lines VDL, the plurality of gate lines GL, the plurality of emission control line EML, and the plurality of data lines DL may be connected to the pixels PX, and may be disposed on the front surface 201. The plurality of first driving voltage lines VDL, the plurality of gate lines GL, the plurality of emission control line EML, and the plurality of data lines DL may extend both in the display area DA and the non-display area NDA.

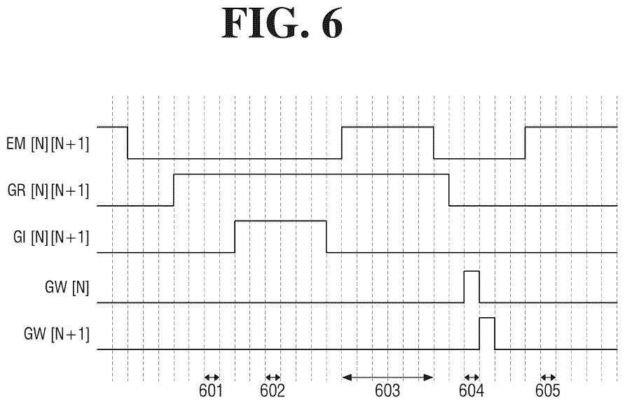

Each of the plurality of pixels PX may be connected to a corresponding gate line GL, a corresponding data line DL, a corresponding emission control line EML, a corresponding first driving voltage line VDL, and the common voltage line (e.g., a second driving voltage line VSL in FIG. 5). Each of the plurality of pixels PX includes a light emitting element LEL, and may include a plurality of thin film transistors and one or more capacitors as a pixel driving circuit PC for driving the light emitting element LEL. The pixel driving circuit PC included in each pixel PX will be described later in detail with reference to FIGS. 5 and 6.

The timing controller 410 may receive a data signal DATA and timing signals from the circuit board 120. Based on the timing signals, the timing controller 410 may control an operation timing of the data driver 440 by generating a data control signal DCS, may control an operation timing of the gate driver 420 by generating a gate control signal GCS, and may control an operation timing of the emission control driver 430 by generating an emission control signal ECS.

The data driver 440 may convert the data signal DATA into analog data voltages and supply the analog data voltages to the data lines DL. The gate signals of the gate driver 420 may select the pixels PX to which the data voltage is supplied, and the selected pixels PX may receive the data voltage through the data lines DL.

The power supply unit 130 may be disposed on the circuit board 120, and may supply a power voltage to the display driving circuit 210 and the display panel 110. The power supply unit 130 may generate a driving voltage and supply the driving voltage to the first driving voltage line VDL, and may generate a common voltage and supply the common voltage to a common electrode (e.g., a cathode electrode CE in FIG. 8) common to (i.e., shared by) the light emitting elements LEL of the plurality of pixels PX.

The gate driver 420 may supply gate signals (GR, GI, and GW in FIG. 5) to the gate lines GL.

The emission control driver 430 may supply emission signals (EM in FIG. 5) to the emission control lines EML.

FIG. 5 is a circuit diagram of one pixel of the display device according to an embodiment.

Referring to FIG. 5, the pixel PX may include the light emitting element LEL (e.g., an organic light emitting diode) as a display element and the pixel driving circuit PC connected to the light emitting element LEL. The pixel driving circuit PC may include first to fifth thin film transistors T1, T2, T3, T4, and T5, and first and second capacitors C1 and C2. The first thin film transistor T1 may be a driving transistor whose a source-drain current is determined according to a gate-source voltage, and each of the second to fifth thin film transistors T2 to T5 may be a switching transistor that is turned on/off according to a gate-source voltage, substantially a gate voltage. The first to fifth thin film transistors T1, T2, T3, T4, and T5 may be oxide-based thin film transistors (i.e., oxide semiconductor thin film transistors). Depending on the type (p-type or n-type) and/or operating conditions of transistor, a first electrode of each of the first to fifth thin film transistors T1, T2, T3, T4, and T5 may be a source electrode (SE in FIG. 8) or a drain electrode (DE in FIG. 8), and a second electrode thereof may be an electrode different from the first electrode. For example, when the first electrode is the source electrode SE, the second electrode may be the drain electrode DE.

The pixel PX may be connected to a first gate line GWL transmitting a first gate signal GW, a second gate line GIL transmitting a second gate signal GI, a third gate line GRL transmitting a third gate signal GR, an emission control line EML transmitting an emission control signal EM, and a data line DL transmitting a data signal DATA. A first driving voltage line VDL may transmit a first driving voltage ELVDD to the first thin film transistor T1. An initialization voltage line VIL may transmit an initialization voltage VINT to the light emitting element LEL (e.g., the organic light emitting diode). A reference voltage line VRL may transmit a reference voltage VREF to the gate electrode of the first thin film transistor T1. Meanwhile, depending on the pixel structure, the initialization voltage line VIL may include a plurality of initialization voltage lines VIL (e.g., a first initialization voltage line and a second initialization voltage line) that transmit different initialization voltages.

The first to fifth thin film transistors T1, T2, T3, T4, and T5 may include an oxide semiconductor material. The oxide semiconductor has high carrier mobility and a low leakage current, and thus, a voltage drop is not large even though a driving time is long. For example, since the oxide semiconductor does not significantly change a color of an image due to a voltage drop even when driven at a low frequency, the oxide semiconductor may be driven at a low frequency. Therefore, since the first to fifth thin film transistors T1, T2, T3, T4, and T5 include the oxide semiconductor material, generation of leakage current may be prevented and power consumption may be reduced. Oxide semiconductor transistors do not require a crystallization process by excimer laser annealing (ELA), which is a process of forming low-temperature polycrystalline silicon (LTPS) semiconductor transistors, and thus manufacturing costs thereof may be reduced.

Since the oxide semiconductor is sensitive to light, fluctuations in the amount of current or the like may occur due to external light. Therefore, it may be considered to absorb or reflect external light by disposing a metal layer on a lower side of the oxide semiconductor. At least some of the first to fifth thin film transistors T1, T2, T3, T4, and T5 may be double gate transistors having a lower gate electrode (e.g., a counter gate electrode). The illustrated example illustrates that the first thin film transistor T1 is a double gate transistor, but the present disclosure is not limited thereto.

The first thin film transistor T1 includes a gate electrode connected to a first node N1 (or a gate node), a first electrode connected to a second node N2, and a second electrode connected to a third node N3. The second node N2 may be a node connected to a second electrode (e.g., a source electrode) of the fifth thin film transistor T5. The third node N3 may be a node connected to an anode electrode (ANE in FIG. 8) (e.g., a pixel electrode) of the light emitting element LEL. The first thin film transistor T1 may serve as a driving transistor, and may receive the data signal DATA according to a switching operation of a second thin film transistor T2 and control the magnitude (e.g., amount of current) of a driving current Id flowing to the light emitting element LEL.

The second thin film transistor T2 (e.g., a data write transistor) includes a gate electrode connected to the first gate line GWL, a first electrode connected to the data line DL, and the second electrode connected to the first node N1 (or the gate electrode of the first thin film transistor T1). The second thin film transistor T2 may be turned on according to the first gate signal GW transmitted to the first gate line GWL to electrically connect the data line DL and the first node N1, and may transmit the data signal DATA transmitted through the data line DL to the first node N1.

The third thin film transistor T3 (e.g., a first initialization transistor) includes a gate electrode connected to the third gate line GRL, a first electrode connected to the reference voltage line VRL, and a second electrode connected to the first node N1 (or the gate electrode of the first thin film transistor T1). The third thin film transistor T3 may be turned on according to the third gate signal GR transmitted through the third gate line GRL to transmit the reference voltage VREF transmitted through the reference voltage line VRL to the first node N1.

The fourth thin film transistor T4 (e.g., a second initialization transistor) includes a gate electrode connected to the second gate line GIL, a first electrode connected to the third node N3 (or the second electrode of the first thin film transistor T1), and a second electrode connected to the initialization voltage line VIL. The fourth thin film transistor T4 may be turned on according to the second gate signal GI transmitted through the second gate line GIL to transmit the initialization voltage VINT transmitted through the initialization voltage line VIL to the third node N3.

The fifth thin film transistor T5 (e.g., an emission control transistor) includes a gate electrode connected to the emission control line EML, a first electrode connected to the first driving voltage line VDL, and a second electrode connected to the second node N2 (or the first electrode of the first thin film transistor T1). The fifth thin film transistor T5 may be turned on or off according to the emission control signal EM transmitted through the emission control line EML.

The first capacitor C1 may be disposed between the first node N1 and the third node N3. The first capacitor C1, which is a storage capacitor, may store a voltage corresponding to a threshold voltage of the first thin film transistor T1 and the data signal DATA.

The second capacitor C2 may be disposed between the third node N3 and the first driving voltage line VDL.

The light emitting element LEL may include a pixel electrode (e.g., an anode electrode ANE in FIG. 8) and a common electrode (e.g., a cathode electrode CE in FIG. 8) facing the pixel electrode, and the common electrode may be applied with a second driving voltage ELVSS. The common electrode may be connected to the second driving voltage line VSL transmitting the second driving voltage ELVSS. The common electrode may be commonly connected to the plurality of pixels PX.

FIG. 6 is a view illustrating a driving timing of a pixel driving circuit illustrated in FIG. 5.

In FIG. 6, EM[N][N+1] is a driving timing of an emission control signal EM supplied to the pixel driving circuit PC of the pixel PX disposed in an N-th row and an N+1-th row. In FIG. 6, GR[N][N+1] is a driving timing of a third gate signal GR supplied to the pixel driving circuit PC of the pixel PX disposed in the N-th row and the N+1-th row. In FIG. 6, GI[N][N+1] is a driving timing of a second gate signal GI supplied to the pixel driving circuit PC of the pixel PX disposed in the N-th row and the N+1-th row. In FIG. 6, GW[N] is a driving timing of a first gate signal GW supplied to the pixel driving circuit PC of the pixel PX disposed in the N-th row. In FIG. 6, GW[N+1] is a driving timing of a first gate signal GW supplied to the pixel driving circuit PC of the pixel PX disposed in the N+1-th row.

Referring to FIG. 6, the pixel driving circuit PC may operate in a first period 601, a second period 602, a third period 603, a fourth period 604, and a fifth period 605 separated from each other during one frame. Hereinafter, an operation of the pixel driving circuit PC of the pixel PX disposed in the N-th row will be mainly described.

The pixel driving circuit PC receives the third gate signal GR in a gate-on voltage state (e.g., a high state) in the first period 601. In the first period 601, the first gate signal GW, the second gate signal GI, and the emission control signal EM are in a gate-off voltage state (e.g., a low state). The third thin film transistor T3 is turned on in response to the third gate signal GR and transmits the reference voltage VREF to the first node N1. Accordingly, the first node N1 is initialized to the reference voltage VREF.

The pixel driving circuit PC receives the second gate signal GI and the third gate signal GR in a gate-on voltage state (e.g., a high state) in the second period 602. In the second period 602, the first gate signal GW and the emission control signal EM are in a gate-off voltage state (e.g., a low state). The fourth thin film transistor T4 is turned on in response to the second gate signal GI and transmits the initialization voltage VINT to the third node N3. Accordingly, the third node N3 is initialized to the initialization voltage VINT. In the second period 602, the third thin film transistor T3 maintains a turned-on state.

The pixel driving circuit PC receives the emission control signal EM and the third gate signal GR in a gate-on voltage state (e.g., a high state) in the third period 603. In the third period 603, the first gate signal GW and the second gate signal GI are in a gate-off voltage state (e.g., a low state). The fifth thin film transistor T5 may be turned on in response to the emission control signal EM, and may transmit the first driving voltage ELVDD to the second node N2. The third thin film transistor T3 maintains a turned-on state, and thus the first node N1 maintains the reference voltage VREF. The first thin film transistor T1 forms a current path connecting the second node N2 and the third node N3. The first thin film transistor T1 may be turned off when a gate voltage thereof is less than or equal to a difference between the reference voltage and a threshold voltage of the first thin film transistor T1. The first capacitor C1 may store a voltage including the threshold voltage Vth of the first thin film transistor T1. The third period 603 may be a compensation period for compensating for the threshold voltage of the first thin film transistor T1.

The pixel driving circuit PC receives the first gate signal GW in a gate-on voltage state (e.g., a high state) in the fourth period 604. In the fourth period 604, the second gate signal GI, the third gate signal GR, and the emission control signal EM are in a gate-off voltage state (e.g., a low state). The second thin film transistor T2 may be turned on in response to the first gate signal GW and may transmit the data signal DATA to the first node N1. Accordingly, the first node N1 has a data voltage in which the threshold voltage of the first thin film transistor T1 is compensated.

The pixel driving circuit PC receives the emission control signal EM, which is in a gate-on voltage state (e.g., a high state) in the fifth period 605, and the first thin film transistor T1 supplies a driving current Id corresponding to the data signal DATA to the light emitting element LEL.

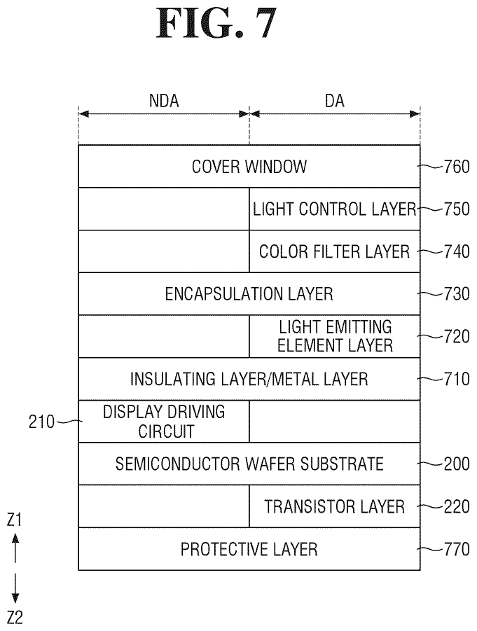

FIG. 7 is a view schematically illustrating a stacked structure of each of a non-display area and a display area of the display panel according to an embodiment. FIG. 8 is a cross-sectional view of each of the non-display area and the display area of the display panel according to an embodiment. FIGS. 7 and 8 exemplarily illustrate cross-sectional structures obtained by cutting a portion of the non-display area and a portion of the display area.

Referring to FIGS. 7 and 8, the display panel employs the semiconductor wafer substrate as a base substrate. The CMOS layer including the display driving circuit 210 and the light emitting element layer 720 including the light emitting element LEL are sequentially stacked in a first direction Z1 from the front surface 201 of the semiconductor wafer substrate 200. The transistor layer 220 including the pixel driving circuits PC is disposed in a second direction Z2 from the rear surface 202 of the semiconductor wafer substrate 200. The transistor layer 220 includes oxide-based thin film transistors including an oxide semiconductor material.

According to the present disclosure, by implementing the pixel driving circuits using the oxide-based thin film transistors, it is possible to provide a display panel capable of low-frequency driving. For example, the display panel may be driven at a variable frequency of about 1 Hz to 120 Hz, and thus power consumption may be reduced.

Hereinafter, a stacked structure of the display panel according to an embodiment of the present disclosure will be described in more detail.

The semiconductor wafer substrate 200 may be a silicon substrate, a germanium substrate, or a silicon-germanium substrate. The semiconductor wafer substrate 200 may be a substrate doped with first-type impurities.

The CMOS layer including a MOSFET and wiring electrodes connected to the MOSFET is disposed in the first direction Z1, which is a direction from the semiconductor wafer substrate 200 toward the front surface 201 thereof. The CMOS layer includes an n-type MOSFET and/or a p-type MOSFET. The first type impurity may be a p-type impurity, and the second type impurity may be an n-type impurity. In an embodiment, the first type impurity may be an n-type impurity, and the second type impurity may be a p-type impurity.

Herein, an n-type MOSFET MOS included in the CMOS layer will be described as an example. The n-type MOSFET MOS may include a well region W1 doped with an n-type impurity in a substrate doped with a p-type impurity. The well region W1 may include a first low-concentration impurity region LDD1 and a second low-concentration impurity region LDD2 having a relatively lower impurity concentration than other portions. The first low-concentration impurity region LDD1 may define a source region S1, and the second low-concentration impurity region LDD2 may define a drain region D1. A channel CH disposed to overlap the gate G1 is defined between the first low-concentration impurity region LDD1 and the second low-concentration impurity region LDD2. An oxide film GI1, which is an insulating layer, may be disposed between the gate G1 and the well region W1.

The MOSFETs MOS disposed at the front surface 201 of the semiconductor wafer substrate 200 constitute the display driving circuit 210, and the display driving circuit 210 is disposed in the non-display area NDA of the display panel 110.

A wiring layer 710 including at least one insulating layer VIA200 and wiring electrodes CE210 is disposed in the first direction Z1 from the CMOS layer including the MOSFETs MOS. For example, the wiring layer 710 may be disposed on or may be stacked on the CMOS layer in the first direction Z1. The wiring electrodes CE210 may connect the MOSFETs MOS to each other through contact holes CT210 penetrating through a portion of the insulating layer VIA200. For example, the wiring electrodes CE210 may be electrically connected to a first wiring electrode CE110 connected to the source region S1 through a source contact hole CT110 of the MOSFET MOS, or may be electrically connected to a second wiring electrode CE120 connected to the drain region D1 through a drain contact hole CT120 of the MOSFET MOS.

The second wiring electrode CE120 of some MOSFETs MOS may be electrically connected to a second contact hole CT500 penetrating through the semiconductor wafer substrate 200 to drive the transistor layer 220 disposed on the rear surface 202 of the semiconductor wafer substrate 200, that is, the pixel driving circuit PC. The second contact hole CT500 may be filled with a second through-substrate via which is an electrical interconnect passing vertically through the semiconductor wafer substrate 200 to conduct electrical signals from one side of the semiconductor wafer substrate 200 to the other. The second contact hole CT500 may be interchangeably referred to as the second through-substrate via. The second contact hole CT500 may be connected to a pad connected to a fan-out line (not illustrated) in the non-display area NDA. Here, the fan-out line is electrically connected to the thin film transistor TFT of the pixel driving circuit PC disposed in the display area DA. Therefore, the MOSFETs MOS of the display driving circuit 210 may control the pixel driving circuit PC disposed in the display area DA through the second contact hole CT500 and the fan-out line.

A light emitting element layer 720 including a light emitting element LEL is disposed in the first direction Z1 from the wiring layer 710 including at least one insulating layer VIA200 and the wiring electrodes CE210. For example, the light emitting element layer 720 may be stacked on or may be disposed on the wiring layer 710. The light emitting element LEL is connected to the transistor layer 220 disposed on the rear surface 202 of the semiconductor wafer substrate 200, that is, the pixel driving circuit PC through a first contact hole CT300 penetrating through the semiconductor wafer substrate 200, the CMOS layer, and at least one insulating layer VIA200. The first contact hole CT300 may be filled with a first through-substrate conductive via. The first contact hole CT300 may be interchangeably referred to as the first through-substrate via which is an electrical interconnect passing vertically through the semiconductor wafer substrate 200 to conduct electrical signals from one side of the semiconductor wafer substrate 200 to the other.

The light emitting element LEL includes an anode electrode ANE connected to the pixel driving circuit PC, a light emitting layer EL covering the anode electrode ANE, and a cathode electrode CE covering the light emitting layer EL. The anode electrode ANE is connected to the pixel driving circuit PC through the first contact hole CT300. At least one connection electrode CE220 may be disposed between the anode electrode ANE and the first contact hole CT300 to electrically connect the anode electrode ANE and the first contact hole CT300 with each other through the contact holes CT210 penetrating through a portion of the insulating layer VIA200. For example, the light emitting element LEL and the pixel driving circuit PC may be electrically connected with each other through the first contact hole CT300 and at least one connection electrode CE220.

The light emitting element LEL includes an anode electrode ANE, a light emitting layer EL, and a cathode electrode CE. The anode electrode ANE may be connected to the thin film transistor TFT through a contact hole CT510 penetrating through a portion of an insulating layer 944 of the transistor layer 220. The light emitting layer EL may cover the anode electrode ANE. The cathode electrode CE may cover the light emitting layer EL.

The light emitting element layer 720 further includes a pixel defining film PDL that partitions a light emitting area of the light emitting element LEL and a spacer (or a partition wall) disposed on the pixel defining film PDL. The pixel defining film PDL and spacer may be formed as an organic film made of an acryl resin, an epoxy resin, a phenolic resin, a polyamide resin, or a polyimide resin.

An encapsulation layer 730 covering the light emitting element LEL is disposed in the first direction Z1 from the light emitting element layer 720. For example, the encapsulation layer 730 may be stacked on or may be disposed on the light emitting element layer 720. The encapsulation layer 730 may include at least one inorganic film to prevent oxygen or moisture from permeating into the light emitting element layer 720. The encapsulation layer 730 may further include at least one organic film to protect the light emitting element layer 720 from foreign materials such as dust.

A color filter layer 740 including a color filter CF is disposed in the first direction Z1 from the encapsulation layer 730. For example, the color filter layer 740 may be stacked on or may be disposed on the encapsulation layer 730. The color filter CF may include a red color filter that transmits red light, a green color filter that transmits green light, and a blue color filter that transmits blue light, but the present disclosure is not limited thereto. The color filter layer 740 is provided when the light emitting element LEL of the light emitting element layer 720 emits white light. If the light emitting element LEL of the light emitting element layer 720 directly emits red light, green light, and blue light respectively, the color filter layer 740 may be omitted.

A light control layer 750 including a refractive film RM is disposed in the first direction Z1 from the color filter layer 740. For example, the light control layer 750 may be stacked on or may be disposed on the color filter layer 740. The refractive film RM may refract incident light so that the light emitted from the light emitting element layer 720 is directed toward a normal direction of the display panel 110 (i.e., the first direction Z1). The refractive film RM may also be referred to as a light control pattern.

A cover window 760 may be disposed in the first direction Z1 from the light control layer 750. For example, the cover window 760 may be stacked on or may be disposed on the light control layer 750. The cover window 760 may include or may be formed of a glass material, but the present disclosure is not limited thereto. Although not illustrated, at least one protective layer may be further disposed between the cover window 760 and the light control layer 750. The protective layer may include or may be, for example, a protective film.

A transistor layer 220 including a thin film transistor TFT and connection electrodes CE410 connected to the thin film transistor TFT is disposed in the second direction Z2, which is a direction from the semiconductor wafer substrate 200 toward the rear surface 202 thereof. The plurality of connection electrodes CE410 may be connected to each other through contact holes CT410.

The thin film transistors TFT disposed on the rear surface 202 of the semiconductor wafer substrate 200 constitute a plurality of pixel driving circuits PC, and each of the pixel driving circuits PC are configured to drive a corresponding light emitting element LEL. For example, the thin film transistors TFT disposed on the rear surface 202 of the semiconductor wafer substrate 200 may constitute the first to fifth thin film transistors T1, T2, T3, T4, and T5 described with reference to FIG. 5.

The thin film transistors TFT (e.g., T1, T2, T3, T4, and T5 in FIG. 5) may include an active layer ACT, a gate electrode GE, a drain electrode DE, and a source electrode SE disposed on the rear surface 202 of the semiconductor wafer substrate 200. The active layer ACT includes an oxide semiconductor material.

The transistor layer 220 further includes capacitor electrodes CPE1 and CPE2 disposed in the second direction Z2 from the thin film transistor TFT. For example, the capacitor electrodes CPE1 and CPE2 may be disposed below the thin film transistor TFT in the second direction Z2. The capacitor electrodes CPE1 and CPE2 may be disposed to face each other in the second direction Z2 (i.e., may overlap each other in the second direction Z2).

In the transistor layer 220, some of the thin film transistors TFT may be connected to the light emitting element LEL disposed on the front surface 201 of the semiconductor wafer substrate 200 through the first contact hole CT300.

In the transistor layer 220, some of the thin film transistors TFT are connected to the pad disposed in the non-display area NDA through the fan-out lines. The pad is connected to the CMOS layer disposed on the front surface 201 of the semiconductor wafer substrate 200 through the second contact hole CT500. Therefore, in the transistor layer 220, some of the thin film transistors TFT may be connected to the display driving circuit 210 disposed on the front surface 201 of the semiconductor wafer substrate 200 through the second contact hole CT500.

A protective layer 770 may be disposed in the second direction Z2 from the transistor layer 220. For example, the protective layer 770 may be stacked on or may be disposed on the transistor layer 220 in the second direction Z2. The protective layer 770 may include a glass material, but the present disclosure is not limited thereto. Although not illustrated, the protective layer 770 may further include, for example, a protective film.

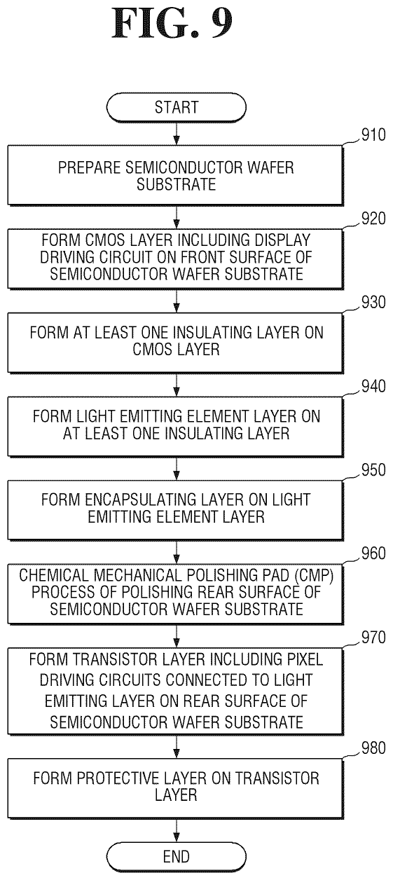

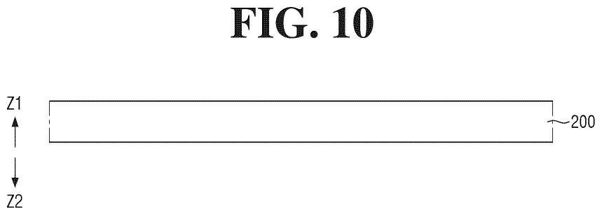

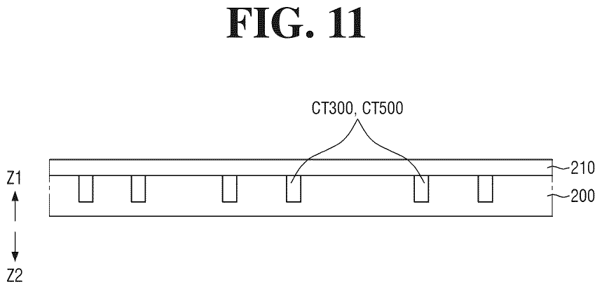

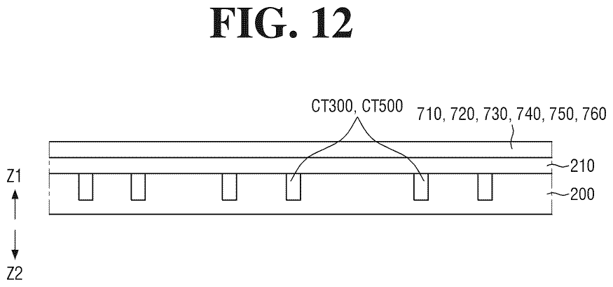

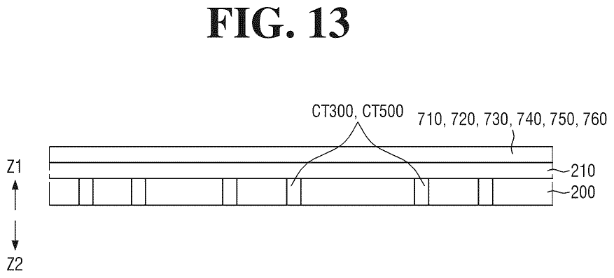

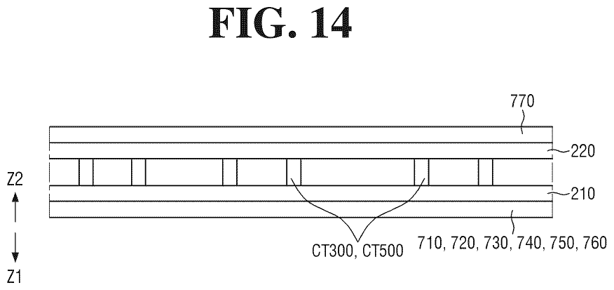

FIG. 9 is a flowchart illustrating at least a portion of a process of manufacturing a display device according to an embodiment. FIG. 10 is a view illustrating a step of preparing a semiconductor wafer substrate. FIG. 11 is a view illustrating a step of forming a CMOS layer on a front surface of the semiconductor wafer substrate. FIG. 12 is a view illustrating a step of forming a wiring layer, a light emitting element layer, an encapsulation layer, a color filter layer, a light control layer and a cover window on the CMOS layer. FIG. 13 is a view illustrating a step of a chemical mechanical polishing (CMP) process. FIG. 14 is a view illustrating a step of forming a transistor layer and a protective layer on a rear surface of the semiconductor wafer substrate.

At least some process steps mentioned with reference to other drawings in the present disclosure may be added before or after each manufacturing process as described with reference to FIGS. 9 to 14. A process of manufacturing a known semiconductor and/or a process of manufacturing a known display panel may be added before or after each manufacturing process as described with reference to FIGS. 9 to 14.

Hereinafter, at least a portion of a process of manufacturing the display device 10 according to an embodiment will be described with reference to FIGS. 8, and 9 to 14.

Referring to FIGS. 9 and 10, in step 910, a semiconductor wafer substrate 200 may be prepared. The semiconductor wafer substrate 200 may be a silicon substrate, a germanium substrate, or a silicon-germanium substrate. The semiconductor wafer substrate 200 may be a substrate doped with first-type impurities.

Referring to FIGS. 8, 9, and 11, in step 920, a CMOS layer may be formed on a front surface 201 of the semiconductor wafer substrate 200. The CMOS layer includes an n-type MOSFET and/or a p-type MOSFET. The first type impurity may be a p-type impurity, and the second type impurity may be an n-type impurity. In an embodiment, the first type impurity may be an n-type impurity, and the second type impurity may be a p-type impurity. MOSFETs MOS of the CMOS layer may constitute a display driving circuit 210. The display driving circuit 210 may be disposed in the non-display area NDA.

The CMOS layer may include a first contact hole CT300 and a second contact hole CT500 partially penetrating the semiconductor wafer substrate 200. The first contact hole CT300 may connect a transistor layer 220, which will be disposed on a rear surface 202 of the semiconductor wafer substrate 200, that is, a pixel driving circuit PC, to a light emitting element layer 720, which will be disposed on the CMOS layer. The second contact hole CT500 may connect the transistor layer 220, which will be disposed on the rear surface 202 of the semiconductor wafer substrate 200, that is, the pixel driving circuit PC, to the display driving circuit 210.

Referring to FIGS. 8, 9 and 12, in step 930, a wiring layer 710 including at least one insulating layer VIA200 and wiring electrodes CE210 is disposed in the first direction Z1 from the CMOS layer including the MOSFETs MOS. For example, the wiring layer 710 may be stacked on or may be disposed on the CMOS layer. The wiring electrodes CE210 may connect the MOSFETs MOS with each other through contact holes CT210 penetrating through a portion of the insulating layer VIA200. For example, the wiring electrodes CE210 may be electrically connected to a first wiring electrode CE110 connected to the source region S1 through a source contact hole CT110 of the MOSFET MOS, or may be electrically connected to a second wiring electrode CE120 connected to the drain region D1 through a drain contact hole CT120 of the MOSFET MOS.

Referring to FIGS. 8, 9 and 12, in step 940, a light emitting element layer 720 including a light emitting element LEL is disposed in the first direction Z1 from the wiring layer 710 including at least one insulating layer VIA200 and the wiring electrodes CE210. For example, the light emitting element layer 720 may be stacked on or may be disposed on the wiring layer 710. The light emitting element LEL will be connected to the transistor layer 220 to be disposed on the rear surface 202 of the semiconductor wafer substrate 200, that is, the pixel driving circuit PC, through the first contact hole CT300 penetrating through the semiconductor wafer substrate 200, the CMOS layer, and at least one insulating layer VIA200.

Referring to FIGS. 8, 9 and 12, in step 950, the encapsulation layer 730 covering the light emitting element LEL is disposed in the first direction Z1 from the light emitting element layer 720. For example, the encapsulation layer 730 may be stacked on or may be disposed on the light emitting element layer 720. The encapsulation layer 730 may include at least one inorganic film to prevent oxygen or moisture from permeating into the light emitting element layer 720. The encapsulation layer 730 may further include at least one organic film to protect the light emitting element layer 720 from foreign materials such as dust. In addition, although not shown in FIG. 9, referring to FIG. 12, a color filter layer 740, a light control layer 750 and a cover window 760 are formed in the first direction Z1 from the encapsulation layer 730.

Referring to FIGS. 8, 9, and 13, in step 960, a chemical mechanical polishing (CMP) process may be performed on the rear surface 202 of the semiconductor wafer substrate 200. As the CMP process is performed on the semiconductor wafer substrate 200, the first contact hole CT300 and the second contact hole CT500 penetrating through the semiconductor wafer substrate 200 may be exposed.

Referring to FIGS. 8, 9, and 14, in step 970, a transistor layer 220 including pixel driving circuits PC connected to the light emitting element layer 720 is formed on the rear surface 202 of the semiconductor wafer substrate 200. The pixel driving circuit PC includes oxide-based thin film transistors TFT. The thin film transistor TFT includes an active layer ACT, a gate electrode GE, a drain electrode DE, and a source electrode SE disposed on the rear surface 202 of the semiconductor wafer substrate 200. The active layer ACT may include or may be formed of an oxide semiconductor material.

Referring to FIGS. 8, 9 and 14, in step 980, the protective layer 770 is formed in the second direction Z2 from the transistor layer 220. For example, the protective layer 770 may be disposed under the transistor layer 220 in the second direction Z2. The protective layer 770 may include or may be formed of a glass material, but the present disclosure is not limited thereto. Although not illustrated, the protective layer 770 may further include, for example, a protective film.

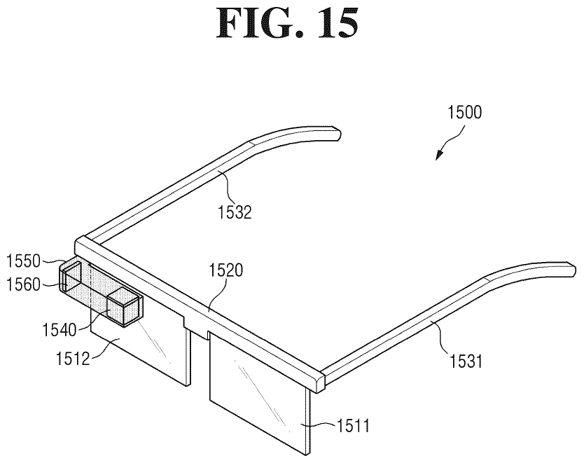

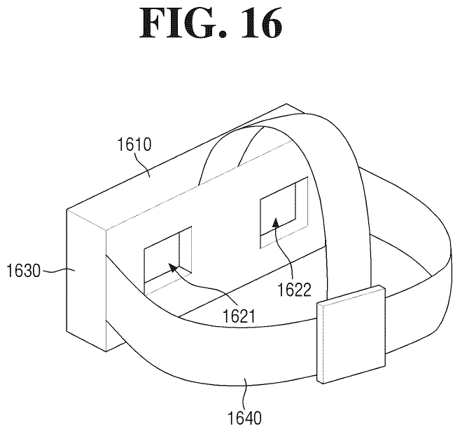

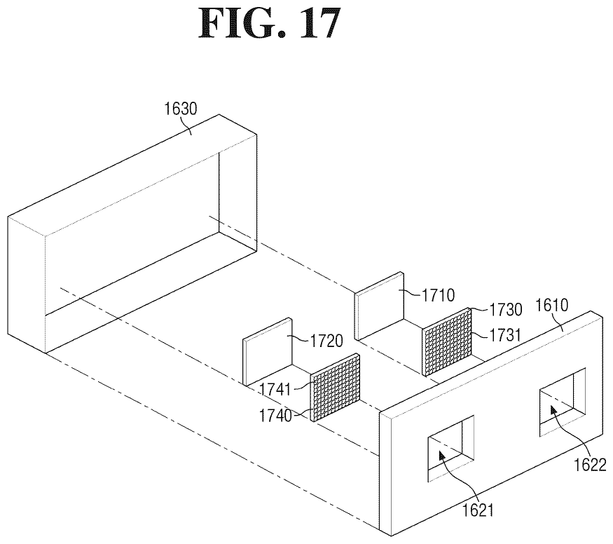

FIG. 15 is a view illustrating a virtual reality device including the display device according to an embodiment. FIGS. 16 and 17 are views illustrating a head mounted display device to which the display device according to an embodiment is applied.

The display device 10 according to an embodiment may be a display device 10 included in a mobile electronic device. The display device 10 according to an embodiment may be included in a wearable device that is developed in the form of glasses or a helmet and focused at a distance close to the user's eyes. For example, the wearable device may be a head mounted display (HMD) device or AR glass. Such a wearable device provides a user with an augmented reality (hereinafter, referred to as “AR”) screen or a virtual reality (hereinafter, referred to as “VR”) screen.

FIG. 15 is a view illustrating a virtual reality device including the display device 10 according to an embodiment.

A virtual reality device 1500 to which a display device 1560 according to an embodiment is applied is illustrated in FIG. 15. Here, the display device 1560 may include, for example, the components as described with reference to FIGS. 1 to 14.

Referring to FIG. 15, the virtual reality device 1500 according to an embodiment may be AR glasses in the form of glasses. The virtual reality device 1500 according to an embodiment may include the display device 1560, a left eye lens 1511, a right eye lens 1512, a support frame 1520, eyeglass frame legs 1531 and 1532, a reflective member 1540, and an accommodating portion 1550.

In FIG. 15, the virtual reality device 1500 in the form of AR glass is exemplified, but the virtual reality device 1500 according to an embodiment may also be applied to an HMD device. The virtual reality device 1500 according to an embodiment is not limited to that illustrated in FIG. 15, and may be applied in various forms in various other mobile electronic devices.

The accommodating portion 1550 may include the display device 1560 and the reflective member 1540. An image displayed on the display device 1560 may be reflected by the reflective member 1540 and provided to a user's right eye through the right eye lens 1512. Accordingly, the user may view a virtual reality image displayed on the display device 1560 through the right eye.

It is illustrated in FIG. 15 that the accommodating portion 1550 is disposed at a right distal end of the support frame 1520, but an embodiment of the present disclosure is not limited thereto. For example, the accommodating portion 1550 may be disposed at a left distal end of the support frame 1520. In this case, an image displayed on the display device 1560 may be reflected by the reflective member 1540 and provided to a user's left eye through the left eye lens 1511. Accordingly, the user may view a virtual reality image displayed on the display device 1560 through the left eye. In an embodiment, the accommodating portions 1550 may be disposed at both the left and right distal ends of the support frame 1520. In this case, the user may view a virtual reality image displayed on the display device 1560 through both the left and right eyes.

FIGS. 16 and 17 are views illustrating an HMD device to which the display device according to an embodiment is applied.

Referring to FIGS. 16 and 17, the display device 10 according to an embodiment may be applied to an HMD device. The HMD device includes a first display device 1710 and a second display device 1720, each of which may be the display device 10 according to an embodiment. The first display device 1710 provides an image to the user's right eye, and the second display device 1720 provides an image to the user's left eye.

A first lens array 1730 may be disposed between the first display device 1710 and an accommodating portion cover 1610. The first lens array 1730 may include a plurality of lenses 1731. The plurality of lenses 1731 may be formed as convex lenses that are convex in a direction of the accommodating portion cover 1610.

A second lens array 1740 may be disposed between the second display device 1720 and the accommodating portion cover 1610. The second lens array 1740 may include a plurality of lenses 1741. The plurality of lenses 1741 may be formed as convex lenses that are convex in a direction of the accommodating portion cover 1610.

The accommodating portion 1630 serves to accommodate the first display device 1710, the second display device 1720, the first lens array 1730, and the second lens array 1740. The accommodating portion 1630 may have an open surface through which the first display device 1710, the second display device 1720, the first lens array 1730, and the second lens array 1740 may be introduced into the inside of the accommodating portion 1630.

The accommodating portion cover 1610 is disposed to cover the open surface of the accommodating portion 1630. The accommodating portion cover 1610 may include a first opening 1621 used to place the user's left eye and a second opening 1622 used to place the user's right eye. It is illustrated in FIGS. 16 and 17 that the first opening 1621 and the second opening 1622 are formed in a quadrangular shape, but the present disclosure is not limited thereto. The first opening 1621 and the second opening 1622 may be formed in a circular shape or an elliptical shape. In an embodiment, the first opening 1621 and the second opening 1622 may be combined to form one opening.

The second opening 1622 may be aligned with the first display device 1710 and the first lens array 1730, and the first opening 1621 may be aligned with the second display device 1720 and the second lens array 1740. Therefore, the user may view the image of the first display device 1710 magnified as a virtual image by the first lens array 1730 through the second opening 1622, and may view the image of the second display device 1720 magnified as a virtual image by the second lens array 1740 through the first opening 1621.

A head mounting band 1640 serves to fix the accommodating portion 1630 to a user's head so that the first opening 1621 and the second opening 1622 of the accommodating portion cover 1610 are disposed on the user's left and right eyes, respectively. The head mounting band 1640 may be connected to an upper surface, a left side surface, and a right side surface of the accommodating portion 1630.

In concluding the detailed description, those skilled in the art will appreciate that many variations and modifications can be made to the embodiments without substantially departing from the principles of the present invention. Therefore, the disclosed embodiments of the invention are used in a generic and descriptive sense only and not for purposes of limitation.

What is claimed is:

1. A display device comprising:
a substrate having a first surface and a second surface opposite to each other;
a first driving element layer disposed on the first surface of the substrate and including a display driving circuit;
at least one insulating layer disposed on the first driving element layer;
a light emitting element layer including a light emitting element and disposed on the at least one insulating layer;
an encapsulation layer disposed on the light emitting element layer;
a second driving element layer disposed on the second surface of the substrate and including a plurality of pixel driving circuits electrically connected to the light emitting element through a first through-substrate via penetrating the substrate, the first driving element layer, and the at least one insulating layer; and
a protective layer disposed on the second driving element layer, wherein the second driving element layer is disposed between the second surface of the substrate and the protective layer.

2. The display device of claim 1,
wherein the plurality of pixel driving circuits of the second driving element layer are electrically connected to the display driving circuit through a second through-substrate via penetrating the substrate.

3. The display device of claim 2,
wherein the substrate includes a display area at which a plurality of pixels including the light emitting element are disposed, and a non-display area outside the display area,
the display driving circuit is disposed at the non-display area, and
the plurality of pixel driving circuits overlap the display area at which the plurality of pixels are disposed.

4. The display device of claim 3,
wherein the plurality of pixel driving circuits are connected to a fan-out line extending from the display area to the non-display area, and
wherein one end of the fan-out line is electrically connected to the display driving circuit through the second through-substrate via penetrating the non-display area of the substrate.

5. The display device of claim 3,
wherein the first through-substrate via penetrates the display area of the substrate.

6. The display device of claim 1,
wherein each of the plurality of pixel driving circuits includes an oxide semiconductor thin film transistor.

7. The display device of claim 1, further comprising:
a color filter layer disposed on the encapsulation layer and including a color filter;
a light control layer disposed on the color filter layer and including a refractive film; and
a cover window disposed on the light control layer.

8. A manufacturing method of a display device, the manufacturing method comprising:
preparing a substrate;
forming a first driving element layer including a display driving circuit on a first surface of the substrate;
forming at least one insulating layer on the first driving element layer;
forming a light emitting element layer including a light emitting element on the at least one insulating layer;
forming an encapsulation layer on the light emitting element layer;
performing a chemical mechanical polishing (CMP) process on a second surface, opposite to the first surface, of the substrate to expose a first through-substrate via electrically connected to the light emitting element;
forming a second driving element layer including a plurality of pixel driving circuits on the second surface of the substrate, wherein the plurality of pixel driving circuits are connected to the light emitting element through the first through-substrate via; and
forming a protective layer on the second driving element layer, wherein the second driving element layer is disposed between the protective layer and the second surface of the substrate.

9. The manufacturing method of claim 8,
wherein the first through-substrate via penetrates the substrate, the first driving element layer, and the at least one insulating layer.

10. The manufacturing method of claim 8,
wherein the plurality of pixel driving circuits of the second driving element layer are electrically connected to the display driving circuit through a second through-substrate via penetrating the substrate.

11. The manufacturing method of claim 10,
wherein the substrate includes a display area at which a plurality of pixels including the light emitting element are disposed, and a non-display area outside the display area,
the display driving circuit is disposed at the non-display area, and
the plurality of pixel driving circuits overlap the display area at which the plurality of pixels are disposed.

12. The manufacturing method of claim 11,
wherein the plurality of pixel driving circuits are connected to a fan-out line extending from the display area to the non-display area, and
wherein one end of the fan-out line is electrically connected to the display driving circuit through the second through-substrate via penetrating the non-display area of the substrate.

13. The manufacturing method of claim 11,
wherein the plurality of pixel driving circuits are electrically connected to the light emitting element through the first through-substrate via penetrating the display area of the substrate.

14. The manufacturing method of claim 8,
wherein each of the plurality of pixel driving circuits includes an oxide semiconductor thin film transistor.

15. The manufacturing method of claim 8, further comprising:
forming a color filter layer including a color filter on the encapsulation layer;
forming a light control layer on the color filter layer; and
attaching a cover window to the light control layer.

16. A mobile electronic device comprising:
a display device including:
a substrate having a first surface and a second surface opposite to each other;
a first driving element layer disposed on the first surface of the substrate and including a display driving circuit;
at least one insulating layer disposed on the first driving element layer;
a light emitting element layer including a light emitting element and disposed on the at least one insulating layer;
an encapsulation layer disposed on the light emitting element layer;
a second driving element layer disposed on the second surface of the substrate and including a plurality of pixel driving circuits electrically connected to the light emitting element through a first through-substrate via penetrating the substrate, the first driving element layer, and the at least one insulating layer; and
a protective layer disposed on the second driving element layer, wherein the second driving element layer is disposed between the second surface of the substrate and the protective layer.

17. The mobile electronic device of claim 16,
wherein the plurality of pixel driving circuits of the second driving element layer are electrically connected to the display driving circuit through a second through-substrate via penetrating the substrate.

18. The mobile electronic device of claim 17,
wherein the substrate includes a display area at which a plurality of pixels including the light emitting element are disposed, and a non-display area outside the display area,
the display driving circuit is disposed at the non-display area, and
the plurality of pixel driving circuits overlap the display area at which the plurality of pixels are disposed.

19. The mobile electronic device of claim 18,
wherein the plurality of pixel driving circuits are connected to a fan-out line extending from the display area to the non-display area, and
wherein one end of the fan-out line is electrically connected to the display driving circuit through the second through-substrate via penetrating the non-display area of the substrate.

20. The mobile electronic device of claim 16,
wherein each of the plurality of pixel driving circuits includes an oxide semiconductor thin film transistor.
